(19) United States
(12) Patent Application Publication
(10) Pub. No.: US 2014/0016686 A1
(43) Pub. Date: Jan. 16, 2014

(54) OVERCOMING MULTIPLE REFLECTIONS IN PACKAGES AND CONNECTORS AT HIGH SPEED BROADBAND SIGNAL ROUTING

(71) Applicant: Marvell World Trade Ltd., St. Michael (BB)

(72) Inventor: Liav BEN ARTSI, Nahariya (IL)

(21) Appl. No.: 13/943,555

(22) Filed: Jul. 16, 2013

Related U.S. Application Data
(60) Provisional application No. 61/672,065, filed on Jul. 16, 2012.

(51) Int. Cl. H04L 25/03; H03H 7/38

(52) U.S. Cl. CPC H04L 25/03878; H03H 7/38
USPC 375/230; 333/33

(57) ABSTRACT

Discussed herein is a semiconductor package and a method of overcoming multiple reflections while transmitting high speed broadband signals through the semiconductor package. The semiconductor package includes at least one trace having a first terminal that is configured to receive a broadband signal and a second terminal configured to output the broadband signal. The semiconductor package includes a stub which is positioned along a longitudinal length of the trace and is configured to reduce broadband reflections in the trace by causing multi-frequency reflections to destructively interfere with at least some broadband reflections in the trace that occur due to impedance discontinuities. The stub parameters such as stub length, stub impedance and the location of the stub along the trace can be determined to minimize signal degradation.

### INCORPORATION BY REFERENCE

This disclosure claims the benefit of U.S. Provisional Application No. 61/672,065, filed on Jul. 16, 2012, the disclosure of which is incorporated herein by reference in its entirety.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

A semiconductor chip generates or receives a high-speed I/O signal at an input or output (I/O) cell and conducts the signal to or from a package terminal. The high-speed I/O signals travel on transmission lines that are intended to maintain signal fidelity over a distance. The I/O cell is a group of integrated active and passive elements. The package terminal couples the semiconductor chip to external devices. The semiconductor chip I/O cell may couple the high-speed I/O signal to a differential pair based transmission line, a single-ended transmission line, or a waveguide. A differential pair based transmission line includes one or more return paths (ground) planes.

The transmission line of the semiconductor chip package is terminated at either end by resistances, capacitances, and reactances that impose impedance discontinuities. Such discontinuities together with the length of the transmission line (a trace) limits signal transmission. Therefore, while transmitting a high-speed broadband signal through the semiconductor chip package, for example a serializer-deserializer (SERDES) differential signal, multiple reflections at different frequencies occur due to the discontinuities in the chip. The multiple discontinuities result in undesired reflections being caused in the broadband signal that is transmitted in the trace. The non-linear signal distortion resulting due to the multiple discontinuities is called ‘insertion loss deviation’ which degrades the quality of the signal propagating through the transmission line.

### SUMMARY

The present disclosure provides for a semiconductor circuit package that comprises at least one trace having a first terminal configured to receive a broadband signal and a second terminal configured to output the broadband signal. The circuit package also includes a stub positioned at a predetermined location along a longitudinal length of the trace, wherein the stub is configured to reduce broadband reflections in the trace by causing multi-frequency reflections that destructively interfere with at least some broadband reflections to be added to signals transmitted along the trace.

According to another embodiment is provided a method of reducing broadband reflections in integrated circuit packaging, the method comprising the steps of: receiving a broadband signal that includes a plurality of high signal frequencies at an input terminal; transferring the broadband signal from the input terminal to a output terminal over a transmission line; and providing a stub, having a predetermined length and a stub impedance, at a predetermined position along the transmission line, to cause multi-frequency signals that destructively interfere with the broadband reflections to be added to signals carried on the transmission line.

According to another embodiment is provided a semiconductor package system comprising: a first printed circuit board and a second printed circuit board, that are connected by a connector that is configured to transmit a broadband signal from the first printed circuit board to the second printed circuit board. The system further includes a stub positioned at a predetermined location along a longitudinal length of the connector conductor, wherein the stub is configured to reduce broadband reflections in the connector, mainly caused by the via's discontinuities at both sides of the connector by causing multi-frequency reflections that destructively interfere with broadband reflections to be added to signals transmitted along the connector.

### BRIEF DESCRIPTION OF THE DRAWINGS

Various embodiments of this disclosure that are provided as examples will be described in detail with reference to the following figures, wherein like numerals reference like elements, and wherein:

FIG. 1A shows an example of a semiconductor IC package having a differential transmission line in accordance with an embodiment;

FIG. 1B shows an example of a semiconductor package mounted on a printed circuit board in accordance with an embodiment;

FIG. 2 illustrates a time domain reflectometry (TDR) plot;

FIGS. 3A and 3B illustrate frequency domain plots depicting insertion loss and return loss of a trace with no discontinuity and a trace with capacitive discontinuities;

FIGS. 4A and 4B illustrates a non-limiting example depicting the insertion loss and return loss of a trace using a stub and a trace with capacitive discontinuities; and

FIG. 5 shows is a flowchart depicting a process of determining trace parameters to mitigate reflections.

### DETAILED DESCRIPTION OF EMBODIMENTS

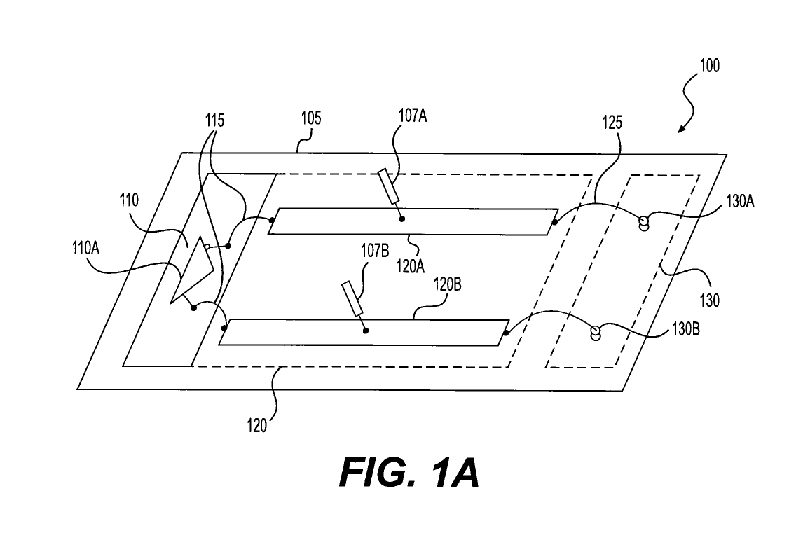

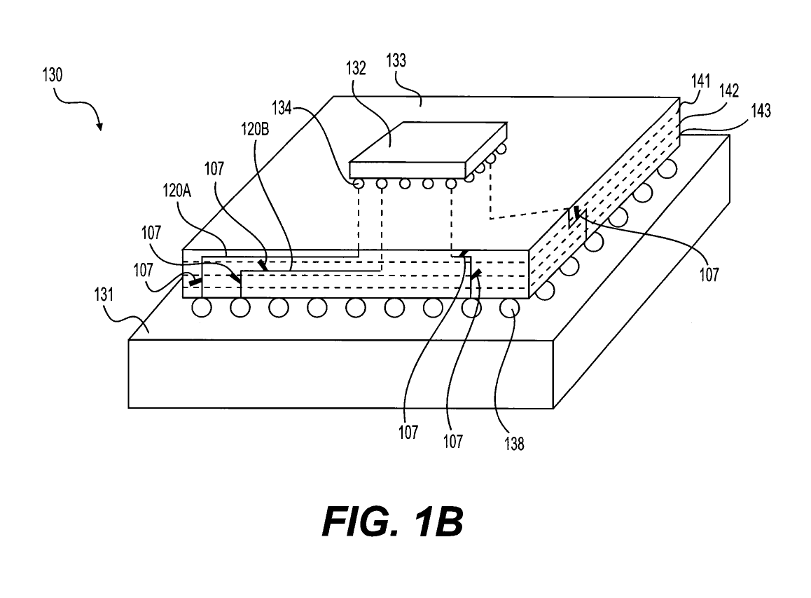

FIG. 1A shows an example of a semiconductor IC package 100 that includes a package body 105 having a semiconductor chip 110 with an input-output (I/O) cell 110A. The package body 105 further includes a transmission line 120 that includes a pair of transmission lines (traces) 120A and 120B that are coupled to the input-output (I/O) cell 110A via a first coupler 115, with the pair of transmission lines 120A and 120B being configured to transmit differential signals. A second coupler 125 couples the transmission lines 120A and 120B to respective terminals 130A and 130B of a terminal 130. As shown, the transmission lines 120A and 120B also include stubs 107A and 107B, respectively.

In operation, the I/O cell 110A generates or receives high-speed digital or analog I/O signals. For example, the I/O cell 110A generates or receives a signal that has a 25.78125 Gbps line rate or data-signaling rate that complies with a 25 Gbps 802.3bj standard. The I/O cell 110A includes circuits that pre-emphasize, equalize, discriminate, and the like. For example, the I/O cell 110A includes a pre-driver that pre-emphasizes a signal or a CTLE (continuous time linear equalizer) that imposes equalization on the received signal.

The impedance of the I/O cell 110A includes intrinsic capacitances, inductances, resistances, or a combination of resistive and reactive components. Further, the impedance of the I/O cell 110A may be purely resistive. In other words, the impedance of the I/O cell 110A may be frequency-dependent that changes from exhibiting an equivalent capacitive reactance component to an equivalent inductive reactance component in one or more frequency bands. The frequency dependent impedance of the I/O cell 110A and the terminals 130 is measured using a vector network analyzer (VNA), for example, and is displayed in terms of time domain reflectometry (TDR) plots, Smith charts, return loss frequency domain plots, and the like. The impedances of the I/O chip 110A may be regarded as constraints with respect to methods for optimizing the transfer characteristics of the transmission line 120.

The first and second couplers 115 and 125 exhibit impedance discontinuities, relative to the transmission line 120 impedance, relative to the system defined characteristic impedance, and/or in addition to the impedance discontinuities of the I/O cell 110A and the terminal 130. The first and second couplers 115 and 125 couple high-speed I/O signals onto or off the transmission line 120. For example, the first and second couplers 115 and 125 couple the high-speed signal between different materials systems, such as between an IC bond pad and a gold-plated nickel lead frame, or between an IC bump pad and the package substrate (by using a bump), or between the package substrate and the printed circuit board by using a ball.

The first and second couplers 115-125 may be inductive, such as ball-wedge wire bonds, wedge-wedge wire bonds, ribbon bonds, ultrasonically welded leads, solder leads, capacitive couplers, bumps, copper pillar bumps and the like. For example, the bond wires can be 1 mil, i.e., 0.001 inch, aluminum or gold bond wires that are ultrasonically welded to a pad of the I/O cell 110A. The first and second couplers 115-125 couple broadband, high line rate signals between the I/O cell 110A and the terminal 130. A broadband signal occupies a bandwidth that is a significant fraction of a digital symbol rate, bit rate, or line rate. The first and second couplers 115-125 exhibit an impedance mismatch or discontinuity between the I/O cell 110 and transmission line 120 and between the transmission line 120 and terminal 130, respectively. For example, the coupler 115 may exhibit an inductive reactance or impedance discontinuity due to a ball-wedge wire bond, bump and a via of a flip-chip package.

The transmission line 120 carries high-speed broadband I/O signals to the terminal 130, in an embodiment. The transmission line 120 is an impedance-controlled structure, such as a microstrip, a stripline, a slotline, a ridge waveguide, a coplanar waveguide (CPW) transmission line or a set of ground-signal-ground (GSG) traces, a set of ground-signal-ground-signal-ground (GSGSG) traces, and the like. The transmission line 120 couples single-ended or differential signals to a corresponding number of elements of terminal 130, such as terminals 130A and 130B.

Further, the transmission line 120 is adjusted by a performance-optimizing method that reduces the insertion loss and maximizes the return loss (when regarded to in positive numbers) of the signal path from I/O cell 110A to terminal 130. Note that the segments 120A and 120B of the transmission line 120 may be adjusted subject to constraints, so that the overall transmission and reflection characteristics of the transmission line 120 is optimum or sufficient. The constraints may include physical, electronic, manufacturing cost constraints, thermal constraints, and environmental constraints, such as capacitance or impedance discontinuities, and the like.

The terminal 130 includes package leads, pins, solderable leads, solder balls, and the like. For example, the terminal 130 includes reflowable or solderable Pb/Sn or Sb/Sn/Ag solder balls in a ball grid array (BGA). The semiconductor package 100 may be soldered to a PCB, a printed wiring board (PWB), and the like. The impedance of the terminal 130 includes intrinsic capacitances, inductances, resistances, or a combination of resistive and reactive components. The impedance of the terminal 130 may be frequency-dependent and may change from exhibiting an inductive reactance component to a capacitive reactance component in one or more frequency bands, for example.

Further, the impedance of the semiconductor I/O cell 110A includes parasitic effects, such as parasitic capacitance causing its total impedance to shift from being an ideal resistance. The I/O cell may also include an internal filter matching scheme which is intended to best match the I/O to the target PCB impedance, but may have some amount of capacitive or inductive characteristic. The transmission lines 120 can be regarded as a broadband impedance matching structure that matches the ideal resistance portion of the I/O cell 110A with the ideal target impedance of the printed PCB (connected to terminals 130a and 130b) and compensates or takes into account the parasitic effects of both the I/O cell 110A and the terminals 130 as well as any other discontinuity that may be present within the package, such as wire bonds, vias, and the like.

The transmission line 120 serves as a communication channel for transmitting broadband signals from the I/O chip 110 to the package terminal 130, in an embodiment. Broadband signals include a wide range of frequencies or a range of frequencies that is a substantial fraction of a digital signaling line rate, including fractions that exceed 100%. For example, a 40 Gbps return to zero (RZ) signal with 20% forward error correction coding (FEC) and a line rate of 48 GHz may include frequency components up to about 120 GHz. In another example, a 10 Gbps data non-return to zero (NRZ) signal may be transmitted at a 10.3125 Gbaud line rate and may include frequency components up to about 15 GHz dependent on the signal's rise time. In yet another example, a 3.125 Gbps broadband signal includes frequency components up to about 4.7 GHz.

Due to the above stated impedance discontinuities, a high speed broadband signal propagating through the transmission line 120 is severely degraded. The signal degradation is caused by frequency dependent distortion that is introduced by the multiple reflections between the trace 120 and discontinuities along or at both ends of the trace such as introduced by 130 and 110. Specifically, the discontinuities cause multiple reflections of the broadband signal within the trace, which results in signal distortion and degrades the output signal quality. To mitigate this effect, stubs 107A and 107B are formed along the trace transmission line, such as along a longitudinal length of the transmission line 120. According to an embodiment, the stubs 107A and 107B are of a similar material as the transmission line 120, and may have an impedance that is similar to the impedance of the transmission line 120 or a different characteristic impedance. However, the stubs 107A and 107B may be of a different material (dielectric and/or metal) or have a different cross sectional configuration than that of the transmission line 120. Further, the stubs 107A and 107B can be formed as a part of the transmission lines 120A and 120B structure or coupled to the transmission line 120 by a connection, such as a wire, a via or could be directly soldered to the transmission line 120, for example.

For each stub 107A and 107B, the stub length, stub impedance, stub width as well as the location of the stub along the longitudinal length of the transmission line 120 is selected such that the stubs are configured to reduce broadband reflections in the trace by causing multi-frequency reflections that destructively interfere with at least some broadband reflections, to be added to signals transmitted along the trace 120. Thus, the signal distortions are controlled at high frequencies while ensuring that the insertion loss at low frequency ranges is within an acceptable limit. The stub parameters as described above can be selected to optimize the broadband frequency characteristics, such as the transfer (insertion loss) or reflection (return loss) of the whole device 100 including discontinuities at the I/O 110, terminals 130, or anywhere within the transmission through the package as well as take into account off-package discontinuities such as board vias located at the device balls.

Since the stubs 107A and 107B are configured to induce multiple reflections into the transmission line 120, it needs to be ensured that reflections are not emitted from the stubs 107A and 107B. Specifically, the end of the stubs away from the transmission line 120, may be terminated with a resistance in order to prevent or reduce signal emissions, or in order to impose an amount of low frequency loss that would further equalize the signal or even introduce some amount of emphasis. According to one embodiment, the stubs 107A and 107B are placed between two ground layers of the circuit package. Alternatively, a circuit package that includes only one ground layer, or a circuit package that has a portion of a layer dedicated for ground could also be used to protect the stubs 107A and 107B from signal emissions and/or lower the amount of emission radiated by the stubs.

In operation, when the transmission lines 120A and 120B are configured to transmit high speed broadband signals from the I/O cell 110A to the terminal 130, of the semiconductor package 100, broadband reflections occur in the transmission lines 120A and 120B due to impedance discontinuities at the input and output side of the semiconductor package 100. Stubs 107A and 107B of a certain length, impedance, and width are positioned along a longitudinal length of the transmission lines 120A and 120B respectively, such that the stubs 107A and 107B reduce broadband reflections in the transmission line 120, by causing multi-frequency reflections that destructively interfere with at least some broadband reflections, to be added to the high speed broadband signals that are transmitted along the transmission line 120. Thus, in broadband, multiple frequency signals, noise introduced by the reflections due to impedance discontinuities is reduced or prevented in the transmission of signals from the I/O cell 110A to the terminal 130.

FIG. 1B shows an example of a semiconductor package 130 mounted on a printed circuit board 131, in accordance with an embodiment. The package 130 includes an integrated circuit chip (IC) 132 that is mounted on an IC package substrate 133 via bump contacts 134. Further, the IC package substrate 133 is mounted on the printed circuit board 131 via ball contacts 138. The package substrate 133 includes multiple connecting layers 141-143.

The bump contacts 134 that connect the IC 132 to the substrate 133, are coupled to the ball contacts (PCB contacts) 138 via transmission lines 120A, 120B. The transmission lines 120A and 120B are generally constructed of horizontal trace portions and vertical via portions. The transmission lines 120A, 120B fan-out inside the package substrate 133 from the IC bump contacts 134 towards respective ball contacts 138. Further, depending on the substrate layer that the transmission lines 120A, 120B are formed, the corresponding vias penetrate though the substrate layers to maintain contact with the PCB ball contacts 138. As shown in FIG. 1B, stubs 107 can be selectively formed on various positions along the horizontal trace portions and/or vertical via portions of the transmission lines 120A and 120B.

In operation, the transmission lines 120A and 120B are configured to transmit high speed broadband signals from/to the IC 132. In doing so, broadband reflections occur in the transmission lines 120A and 120B due to impedance discontinuities of the semiconductor package 130. To account for this phenomenon, stubs 107 of a certain length, impedance, and width are formed along the transmission lines 120A and 120B. In a similar manner to that described above, the stubs 107 reduce broadband reflections, by causing multi-frequency reflections that destructively interfere with at least some broadband reflections. Thus, noise introduced by the reflections due to impedance discontinuities is reduced or prevented in the transmission of signals from the IC 132 to the printed circuit board 131.

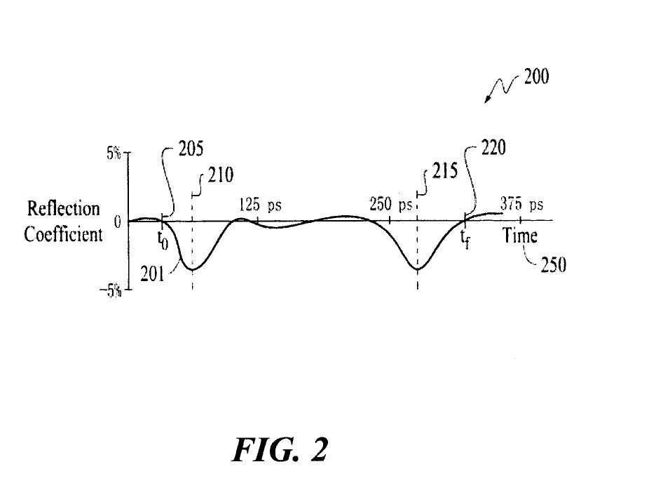

FIG. 2 shows an example of a time domain reflectometry (TDR) plot 200 that includes a TDR plot 201, a starting time t₀ 205, a first reflection 210, a second reflection 215, an ending time 4220 and a time axis 250. The TDR plot 200 shows a voltage reflection coefficient as a function of time. Reflections are caused by impedance discontinuities between or within high-speed sources or generators, transmission structures, and signal destinations or loads. An impedance discontinuity is evident from a TDR plot of a reflection coefficient or impedance versus time, or from a frequency domain return loss curve. The reflection coefficient versus time plot may be converted to an impedance versus time plot and vice versa. For example, for a 100Ω differential impedance transmission line, a TDR reflection plot, such as TDR plot 201, may be transformed into a TDR plot using a 100Ω differential impedance reference.

An impedance discontinuity occurs between the I/O cell 110 and terminal 130, or vice versa, when a TDR plot exhibits localized impedance that is different than a differential, common, even-mode, odd-mode, or characteristic impedance, and the like, of the transmission line 120. For example, the I/O cell 110A and the terminal 130 exhibit 0.25 pF capacitive discontinuities with respect to a differential impedance of the transmission line 120.

The starting time of TDR plot 200, t₀ 205, and the ending time, t_{f} 220, can be described as user-defined starting and ending times. For example, t₀ 205 and t_{f} 220 corresponds to phase reference planes normal to the direction of signal propagation. The phase reference plans are located on an I/O cell 110A bump pad and the terminal 130. The TDR plot 200 is obtained, in an embodiment, using microwave probe techniques that de-embed a microwave probe impedance, a probe pad impedance, or other measurement artifacts. Additionally, the TDR plot may also be obtained by measuring using a TDR or derived from a VNA measurement and performing de-embedding of structures which are printed circuit board or measurement related.

The TDR plot 201 exhibits the effects of impedance discontinuities such as the first and second reflections 210 and 215. The first and second reflections 210 and 215 quantify the degree of mismatch of an impedance continuity relative to a transmission line impedance, such as a differential impedance. For example, the first and second reflections 210 and 215 may be caused by capacitive discontinuities and result in a negative-going reflection coefficient. Note that while TDR plot 201 shows the first and second reflections 210 and 215 from capacitive discontinuities, inductive discontinuities may be present instead of or in addition to.

Further, due the discontinuities in the transmission line, a small portion of the signal power is usually reflected back into the transmission line, resulting in lower output signal power, or a distorted signal at the output, since the reflection is frequency dependent. A parameter return loss is generally used to measure the performance of a transmission line. Return loss is defined as the loss of signal power resulting from the reflection caused at a discontinuity in a transmission line. Return loss is generally expressed in decibels (dB), as a ratio of the reflected signal power to the input signal power. Furthermore, a package characterized by low (on a positive scale) return loss, when attached to a real system, is susceptible to reflections from the system side thus causing multiple reflections between the system and the device and degrading signal quality.

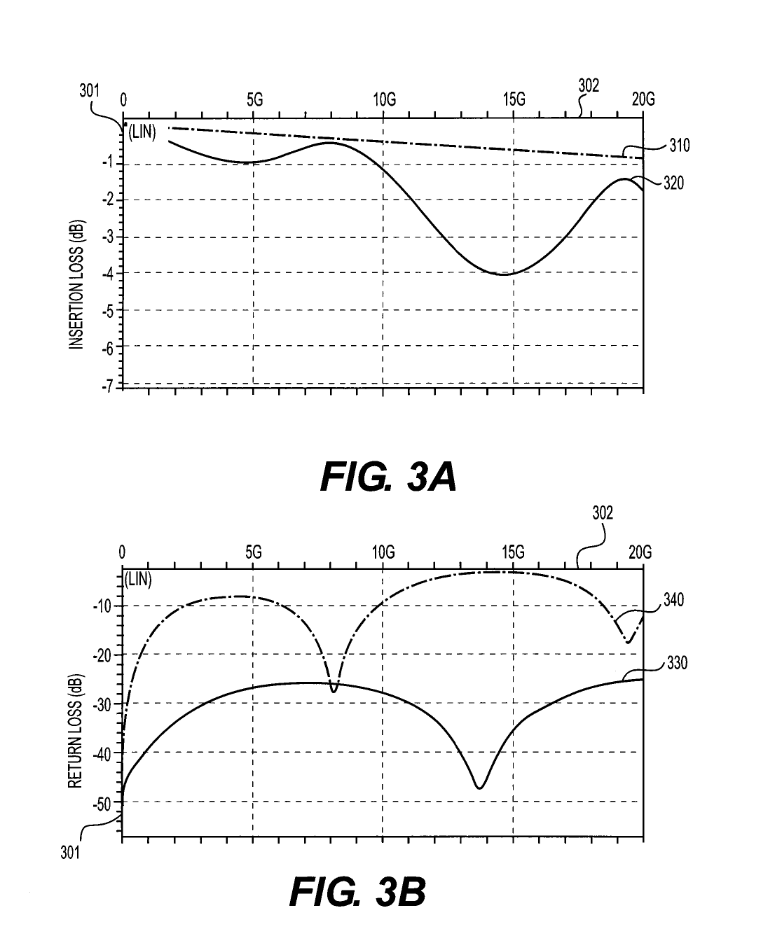

FIGS. 3A and 3B depict frequency domain plots (corresponding to the transmission of digital signals) that quantify the performance of a transmission line (trace) with respect to insertion loss and return loss, respectively.

FIG. 3A shows a frequency domain plot that depicts insertion loss of a trace plotted on the Y axis, 301, for a range of frequencies plotted on the X-axis 302. The insertion loss is represented in the decibel format. FIG. 3A depicts two curves for a trace with no discontinuity 310, and a second curve 320, for a trace that has a capacitive discontinuity of 0.25 pF located at both edges.

The insertion loss of trace 320 incurs signal degradation at high frequencies occurring primarily due to the multiple reflections of the broadband signal propagating through the trace. Specifically, at frequencies ranging from 10 GHz to 15 GHz, the insertion loss for 320 suffers approximately a 3 dB loss as compared to the insertion loss of trace with no discontinuities. Further, curve 310 has loss that is attributed to factors such as dielectric loss, skin effect and copper surface roughness, for example. Curve 320 has loss which is attributed to multiple reflections caused by discontinuities at both ends and/or along the package trace.

FIG. 3B depicts the corresponding return loss for the two traces considered in FIG. 3A. Specifically, the return loss of the trace with no discontinuity is represented as 330, and the return loss for the trace with a capacitive discontinuity of 0.25 pF located at both edges is represented as 340. The curve 330 has a higher return loss (on a positive scale) implying that approximately all the signal induced at the package terminal, or ball is transmitted through the trace. However, the curve 340 has a low return loss thereby indicating that only a small fraction of the input signal power is transmitted through the trace. In this case, due to the discontinuities located in the trace, a significant fraction of the input signal power is reflected. In this case the trace with both discontinuities as depicted and as related to package structure is susceptible to multiple reflections between the system reflected signal and the package reflected signal.

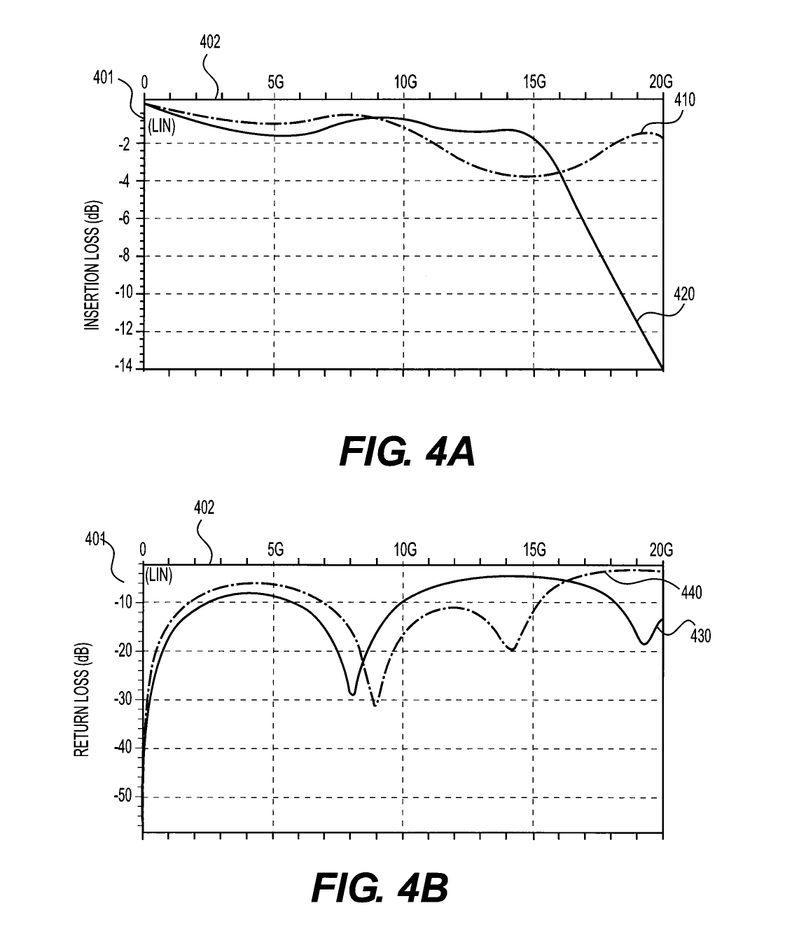

FIGS. 4A and 4B depict a non-limiting example that shows the frequency domain plots that quantify the performance of a transmission line (trace) with respect to insertion loss and return loss respectively, for a trace that has a capacitive discontinuity of 0.25 pF located at both edges, represented by curve 410, and a trace that uses a stub to mitigate the effects of multiple broadband reflections caused due to discontinuities, represented by curve 420, in accordance with an embodiment. At the specific implementation described in FIGS. 4A and 4B, notice that the insertion loss depicted in 410 has relatively high loss above ˜10 GHz and relatively low loss below ˜8 GHz, causing broadband signal frequency related distortion. By applying the methodology described in this application the insertion loss between 10-15 GHz is improved while the lower frequency range (1 GHz-8 GHz) insertion loss is slightly degraded, maintaining a relatively flat response over a wide frequency range.

Similar to FIGS. 3A and 3B, in FIGS. 4A and 4B, the insertion loss/return loss is represented on the Y-axis 401, for a range of frequencies plotted on the X-axis 402. Considering the frequency range of 10 Gz-15 Gz in FIG. 4A, note that curve 420 (while using a stub to mitigate broadband multiple reflections), significantly reduces the insertion loss as compared to curve 410 (for the trace which has capacitive discontinuities and does not use a stub). Further, as shown in FIG. 4B, the return loss for the trace which uses a stub is represented as 440 and the return loss for the trace with a capacitive discontinuity is represented as 430. Note that the trace 440 increases the return loss as compared to the trace with capacitive discontinuities at high frequencies, thereby indicating that by using a stub to mitigate the multiple broadband reflections, a smaller portion of the signal power is reflected back from the trace.

According to another embodiment, the above methods of reducing multiple reflections in transmission traces is applied to a system that includes semiconductor packages mounted on printed circuit boards that are connected by a connector, such as an integrated circuit package for instance. In this embodiment, the connector is configured to transfer high speed signals from one PCB to another. During operation, while transmitting broadband signals from one package to another package, multiple frequency reflections occur in the connector that tends to degrade signal quality.

Thus, to mitigate the reflections in the connector, a stub is formed along a longitudinal length of the connector conductor(s). The stub length, stub impedance, stub width as well as the location of the stub along the longitudinal length of the connector are selected such that the stub is configured to reduce broadband reflections in the connector by causing multi-frequency reflections that destructively interfere with at least some broadband reflections. Thus, the signal distortions are controlled at high frequencies while ensuring that the insertion loss at low frequency ranges is within an acceptable limit.

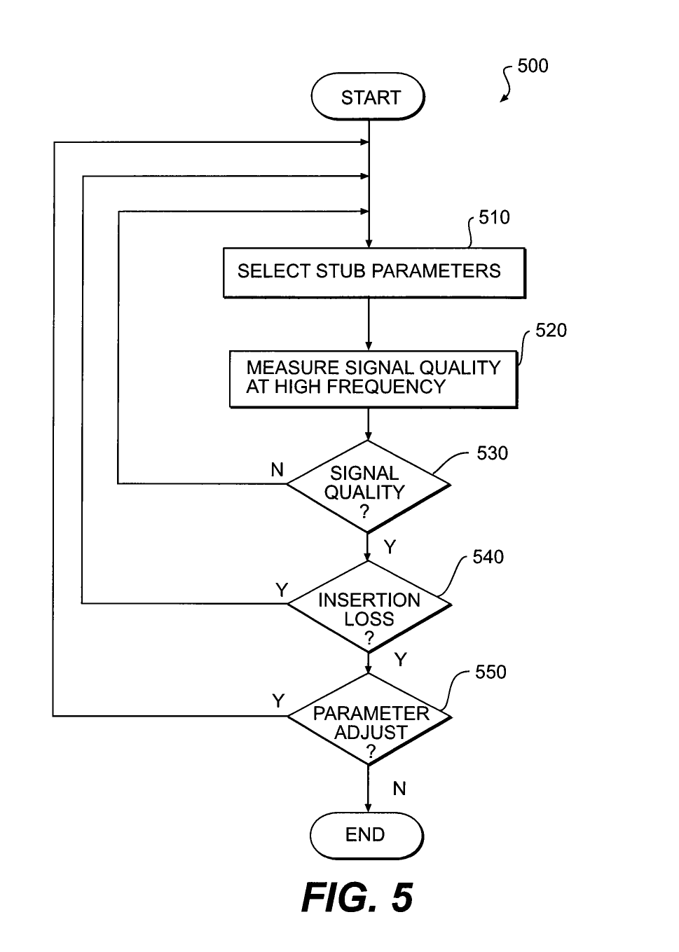

It is noted that numerous techniques can be used to determine stub parameters to overcome broadband reflections of a broadband signal that propagates through a trace of a semiconductor package. FIG. 5 is a flowchart depicting one representative technique. The stub is positioned along a longitudinal length of the trace as shown in FIG. 1 in an embodiment. The stub is configured to reduce broadband reflections in the trace by causing multi-frequency reflections that destructively interfere with at least some broadband reflections, to be added to the broadband signal that is transmitted along the trace.

In 510, the stub parameters such as the position of the stub along the trace, the stub length, stub impedance, and stub width are selected to determine the quality of the signal that is output from the semiconductor package.

In 520, the quality of the signal output from the package, for example at high frequencies, is simulated using an electro-magnetic 3-d/2.5d/2d extractor such as HFSS, ADS or the like, or by using parametric or extracted models for the package trace, stub, vias, balls, etc. and calculate the package or connector S-parameters by using Spice/Matlab or the like. Specifically, signal degradation at high frequencies can be estimated by extracting the package or connector s-parameters including the insertion loss and return loss.

In 530, a query is made to check if the insertion loss and return loss meet the required target. This is determined, for instance, by verifying if the return loss (including the discontinuities at both ends) meet a pre-defined limit. For example, the limit may be determined by a specific standard such as 802.3bj or the like. If the response to the query is affirmative, the process proceeds to 540. If the response to the query is negative, the process loops back to 510 to change at least one parameter of the stub, in order to determine the package or connector quality with the updated stub parameters.

At 540, another query is made to check if the insertion loss is within a predetermined threshold value, for the set of stub parameters selected in 510. If the response to the query is negative, the process simply loops back to 510 to further adjust the stub parameters. If the response to the query is affirmative, the process moves to 550. A predetermined threshold may include limitations on maximum insertion loss as well as maximum allowed insertion loss ripple (deviation—ILD) up to a pre-determined frequency.

In 550, a query is made to check if a further adjustment of the stub parameters is desired. This is performed in the case that former simulation or extraction runs resulted in stub parameters which are hard or not optimal for implementation in the connector or package. If the response to the query is affirmative the process loops back to 510, else the process merely ends.

According to one embodiment, all the parameters of the stub (i.e., the length, impedance, location, and width) are changed at the same time to determine the signal quality for the particular set of stub parameters. Alternatively, according to another embodiment, at least one parameter is set to a fixed value, and the other parameters are adjusted to find a set of stub parameters that maintain an acceptable signal quality. For example, the length of the stub is set to a fixed value due to mechanical and environmental constraints, and the other parameters such as impedance, location etc., are adjusted to determine a set of stub parameters that maintain the signal quality. An optimization process is applied to obtain the best solution.

While aspects of the present disclosure have been described in conjunction with the specific embodiments thereof that are proposed as examples, alternatives, modifications, and variations to the examples may be made. Accordingly, embodiments as set forth herein are intended to be illustrative and not limiting. There are changes that may be made without departing from the scope of the claims set forth below.

What is claimed is:

1. A circuit package comprising:
at least one trace having a first terminal configured to receive a broadband signal and a second terminal configured to output the broadband signal; and
a stub projecting from the trace and positioned at a predetermined location along a longitudinal length of the trace, the stub being configured to reduce reflections in the trace by causing multi-frequency reflections that destructively interfere with at least some broadband reflections to be added to signals transmitted along the trace and improve broad-band insertion loss/return loss.

2. The circuit package of claim 1, wherein the stub is configured to cause the multi-frequency reflections to destructively interfere with at least some, but not all, broadband reflections in the trace.

3. The circuit package of claim 1, wherein the trace has a trace impedance and wherein the stub is of a predetermined length and has a stub impedance, the stub impedance being different than the trace impedance.

4. The circuit package of claim 1, wherein the trace is configured to carry broadband signals having a plurality of frequency components.

5. The circuit package of claim 1, wherein the trace is configured to carry a broadband signal that includes multiple frequency components of magnitude up to 25 gigahertz.

6. The circuit package of claim 1, wherein each trace further includes a reference plane return path that is electromagnetically coupled to the trace and is configured to provide an equi-potential surface.

7. The circuit package of claim 6, wherein the reference plane return path is a ground plane.

8. The circuit package of claim 1, wherein the stub is positioned along the trace so as to reduce a signal loss between the first terminal and the second terminal.

9. The circuit package of claim 1, wherein the stub is of a predetermined length and is configured to reduce a signal loss between the first terminal and the second terminal.

10. The circuit package of claim 1, wherein the stub has a predetermined impedance and is configured to reduce a signal loss between the first terminal and the second terminal.

11. The circuit package of claim 1, wherein the stub is configured to improve broad-band insertion loss/return loss by including at least one of a location along the longitudinal length of the trace where the stub is positioned, an impedance of the stub and a size of the stub.

12. The circuit package of claim 1, wherein the stub is configured to improve insertion loss over a predetermined bandwidth, while maintaining insertion loss deviation below a first predetermined value.

13. The circuit package of claim 1, wherein the stub is configured to improve return loss on a positive loss scale while maintaining the return loss below a second predetermined value.

14. The circuit package of claim 1, further includes a signal input port and a signal output port having a first and a second parasitic capacitance, respectively, and a signal loss between the signal input port and the signal output port is reduced by positioning the stub of a predetermined length and impedance at the predetermined location, the stub being configured to cause multi-frequency reflections to destructively interfere with the broadband reflections to be added to signals transmitted between the signal input port and the signal output port.

15. The circuit package of claim 1, wherein the transferring of broadband signal from the first terminal to the second terminal includes transmitting the broadband signal over a differential pair of traces.

16. A method of reducing broadband reflections in integrated circuit packaging, the method comprising:
receiving a broadband signal that includes a plurality of high signal frequencies at an input terminal;
transferring the broadband signal from the input terminal to a output terminal over a transmission line; and
providing a stub, having a predetermined length and a stub impedance, at a predetermined position along the transmission line, to cause multi-frequency signals that destructively interfere with the broadband reflections to be added to signals carried on the transmission line.

17. The method of claim 16, wherein the transferring of the broadband signal from the input terminal to the output terminal includes conducting the broadband signal over a differential pair of traces.

18. The method of claim 16, further comprising:
minimizing an insertion loss to signals transmitted in the transmission line, over a predetermined low frequency range between the input terminal and the output terminal, by setting the stub impedance to be different than a transmission line impedance.

19. A system comprising:
a first printed circuit board;
a second printed circuit board;
a connector configured to transmit a broadband signal from the first printed circuit board to the second printed circuit board; and
a stub positioned at a predetermined location along a longitudinal length of the connector conductor, the stub configured to reduce broadband reflections in the connector by causing multi-frequency reflections that destructively interfere with broadband reflections to be added to signals transmitted along the connector.

20. The system of claim 19, wherein the first printed circuit board further comprises:
a first signal input port configured to receive a broadband signal from a signal generator having a signal generator impedance;
a first signal output port configured to output the broadband signal to the second printed circuit board; and
at least one first trace that is configured to transfer the broadband signal between the first signal input port and the first signal output port.

21. The system of claim 19, wherein the second printed circuit board further comprises:
a second signal input port configured to receive the broadband signal from the first printed circuit board;
a second signal output port configured to output the received broadband signal; and
at least one second trace that is configured to transfer the broadband signal between the second signal input port and the second signal output port.

22. The system of claim 19, wherein the connector is connected at a first end to a first output port of the first printed circuit board and is connected at another end to a second input port of the second printed circuit board.

23. The system of claim 19, wherein the first printed circuit board, the second printed circuit board, the connector and the stub are coplanar.

24. The system of claim 19, wherein the stub positioned at the predetermined location along the connector conductor has a predetermined length and a stub impedance.
